(19) United States
(12) Patent Application Publication
(10) Pub. No.: US 2025/0217440 A1
(43) Pub. Date: Jul. 3, 2025

(54) MULTI-TIER ANALOG IN-MEMORY COMPUTING DEVICE

(71) Applicant: INTERNATIONAL BUSINESS MACHINES CORPORATION, ARMONK, NY (US)

(72) Inventors: Athanasios Vasilopoulos, KIlchberg (CH); Abhairaj Singh, Adliswil (CH); Irem Boybat Kara, Adliswil (CH); Manuel Le Gallo-Bourdeau, Horgen (CH); Abu Sebastian, Adliswil (CH)

(21) Appl. No.: 18/401,464

(22) Filed: Dec. 30, 2023

(51) Int. Cl. G06F 17/16; G11C 27/00

(52) U.S. Cl. CPC G06F 17/16; G11C 27/005

(57) ABSTRACT

An analog in-memory computing (AIMC) system includes a plurality of tiles. A plurality of vertically stacked tiers are present on each tile. Each tier comprises a crossbar of resistive memory devices, configured to encode a matrix of weights. A digital to analog convert (DAC) is shared by the plurality of tiles. The DAC is configured to encode an input vector to voltage pulses applied on the crossbar. An analog to digital converter (ADC) is shared by the plurality of tiles, and includes a register of counters. The ADC is configured to measure an induced current on each column of the crossbar and digitize the induced current into a digital value. A programmable logic controller is configured to: control the ADC to retain integration values between integrations performed for each tier. An accumulation of partial integration results is performed in-situ of the tile.

### BACKGROUND

### Technical Field

The present disclosure generally relates to computing hardware, and more particularly to a multi-tier analog in-memory computing device.

### Description of the Related Art

Analog In-Memory Computing (AIMC) has been identified as a viable alternative to the conventional von-Neumann computing paradigm. By performing computation in-place (in-memory) the time and energy cost associated with shuffling data between a processing element and a memory is alleviated, leading to more efficient systems.

The elementary component of an AIMC system is the tile. An AIMC tile typically includes a crossbar of resistive memory devices, that will encode the matrix elements of the operation. In addition, a series of Digital-to-Analog Converters (DACs) encode the input vector to the voltage pulses that are applied on the crossbar. A series of Analog-to-Digital Converters (ADCs) measure the induced current and digitize it.

AIMC is particularly of interest for data-heavy workloads, for example, Deep Neural Network (DNN) Inference and other optimization problems. These workloads are dominated by Matrix-Vector Multiply (MVM) operations. AIMC can be used to perform MVM operations in O (1) time complexity and with extreme power efficiency, due to its weight-stationary characteristic. By encoding the Matrix parameters in the conductance of memory elements and applying voltage pulses encoding the Vector, we can exploit Ohm's and Kirchoff's laws to calculate dot products by measuring the produced currents.

### SUMMARY

According to an embodiment of the present disclosure, an analog in-memory computing (AIMC) system is disclosed. The AIMC includes a first tile. The first tile includes two or more stacked tiers. A crossbar of resistive memory devices, including a plurality of columns, is on each tier. The crossbar is configured to encode a matrix of weights. A digital to analog convert (DAC) is coupled to the periphery of the first tile. The DAC is configured to encode an input vector to voltage pulses applied on the crossbar. An analog to digital converter (ADC) is coupled to a periphery of the first tile. The ADC includes a register of counters. The ADC is configured to measure an induced current on each column of the crossbar and digitize the induced current into a digital value. A programmable logic controller is coupled to the first tile, the DAC, and to the ADC. The programmable logic controller is configured to perform a first matrix vector multiplication (MVM) integration on a first tier of the first tile. A first result is obtained from the first MVM integration performed on the first tier. A second MVM integration is performed on a second tier of the first tile. A second result is obtained from the second MVM integration performed on the second tier. The first result and the second result are accumulated into an accumulated digital value of the first tile, represented as a counter value in a register of the ADC.

According to an embodiment of the present disclosure, an analog in-memory computing (AIMC) system is disclosed. The AIMC includes a plurality of tiles. A plurality of vertically stacked tiers are present on each tile. Each tier comprises a crossbar of resistive memory devices, including a plurality of columns. A digital to analog convert (DAC) is shared by the plurality of tiles. The DAC is configured to encode an input vector to voltage pulses applied on the crossbar. An analog to digital converter (ADC) is shared by the plurality of tiles, and includes a register of counters. The ADC is configured to measure an induced current on each column of the crossbar and digitize the induced current into a digital value. A programmable logic controller is coupled to the plurality of tiles, the DAC, and to the ADC. The programmable logic controller is configured to: control the ADC to retain integration values between integrations performed for each tier. An accumulation of partial integration results is performed in-situ of the tile.

According to an embodiment of the present disclosure, a programmable logic controller in an analog in-memory computing (AIMC) system is disclosed. The programmable logic controller includes instructions configured to control an analog to digital converter (ADC) coupled to a multi-tier tile, to retain integration values between integrations performed for each tier in the multi-tier tile. The programmable logic controller performs an accumulation of partial integration results in-situ of the tile.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 is an illustration of a multi-tier tile in an analog in-memory computing system, consistent with an illustrative embodiment.

FIG. 2 is a diagrammatic view of a matrix vector multiple operation, consistent with an illustrative embodiment.

FIG. 3 is a block diagram of an analog in-memory computing system, consistent with an illustrative embodiment.

FIG. 4 is a schematic view of an analog input conversion circuit for an analog in-memory computing system, consistent with an illustrative embodiment.

FIG. 5 is a diagrammatic view of input activation modes for an analog in-memory computing system, consistent with an illustrative embodiment.

FIG. 6 is a block diagram of an analog to digital conversion system, consistent with an illustrative embodiment.

FIG. 7 is a block diagram of a post-processing process for analog to digital conversion bits, consistent with an illustrative embodiment.

FIG. 8 is a block diagram of a post-processing process for analog to digital conversion bits using a right shifting method, consistent with an illustrative embodiment.

FIG. 9 is a block diagram illustrating the mapping of weights in a matrix vector multiple operation, consistent with an illustrative embodiment.

FIG. 10 is a block diagram illustrating a method of processing weights by a crossbar element in a tile, from a matrix whose input vector exceeds the capacity of the crossbar, consistent with an illustrative embodiment.

FIG. 11 is a block diagram illustrating a method of processing weights by a crossbar element in a multi-tier tile, from a matrix whose output dimension exceeds the capacity of the crossbar, consistent with an illustrative embodiment.

FIG. 12 is a block diagram illustrating a method of processing weights by a crossbar element in a multi-tier tile, from a matrix whose input vector and output dimension exceed the capacity of the crossbar, consistent with an illustrative embodiment.

FIG. 13 is a block diagram of a multi-tier tile architecture in an analog in-memory computing system, consistent with an illustrative embodiment.

FIG. 14A is a block diagram illustrating a method of processing a matrix vector multiplication integration in a multi-tier tile within an analog in-memory computing system, consistent with an illustrative embodiment.

FIG. 14B is a block diagram illustrating a method of processing a matrix vector multiplication integration in a multi-tier tile within an analog in-memory computing system when partial input vectors arrive approximately simultaneously for a tile, consistent with an illustrative embodiment.

FIG. 14C is a block diagram illustrating a method of processing a matrix vector multiplication integration in a multi-tier tile within an analog in-memory computing system when partial input vectors arrive at different times for a tile, consistent with an illustrative embodiment.

FIG. 15 is a block diagram of a multi-tier analog in-memory computing device for matrix vector multiplication operations with large matrices and multi-model operation, consistent with an illustrative embodiment.

FIG. 16 is a block diagram of a multi-tier analog in-memory computing device incorporating a down-sampling stage, consistent with an illustrative embodiment.

FIG. 17 is a block diagram of a multi-tier analog in-memory computing device incorporating a sliding window process in an analog to digital converter counter module, consistent with an illustrative embodiment.

FIG. 18 is a block diagram of a multi-tier analog in-memory computing device incorporating a right shift process in an analog to digital converter counter module, consistent with an illustrative embodiment.

FIG. 19 is a block diagram illustrating mapping of a convolutional neural network to a multi-tier analog in-memory computing device, consistent with an illustrative embodiment.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

### Definitions

Analog In-Memory Computing (AIMC), as used herein, refers to a computing paradigm in which memory devices, used in an analog manner, are used to encode data and to perform part or the whole computation associated with a workload (for example, a neural network).

AIMC system, as used herein, refers to a software operable system that comprises analog and possibly digital circuitry and executes computations according to the AIMC paradigm.

Tile, as used herein, refers to non-volatile memory cells in a two-dimensional or three-dimensional array that include transistors or other circuit devices that control the reading and writing of the non-volatile memory cells. In some embodiments, the transistors/circuit devices perform matrix-vector multiple operations.

Tier, as used herein, refers to a two-dimensional slice of a tile.

Two-Dimensional Slice, as used herein, refers to a selected level of a three-dimensional memory array. For example, the memory array of a tile may be of size 512 by 512 and have 64 such levels. A two-dimensional slice is one of these levels that corresponds to a single 512 by 512 array.

Neural network, as used herein, refers to a computational learning system that uses a network of functions to understand and translate a data input of one form into a desired output.

### Overview

The present disclosure generally relates to multi-tier AIMC systems (sometimes referred to as 3D AIMC systems). AIMC systems alleviate the cost, energy, and time associated with shuffling data between processing elements and memories. Analog in memory computing is particularly helpful when there is voluminous data because a classic computer for example, may need a lot of overhead and communication cost in memory.

According to an embodiment of the present disclosure, an analog in-memory computing (AIMC) system is disclosed. The AIMC includes a first tile that includes two or more stacked tiers. A crossbar of resistive memory devices is on each tier. The crossbar is configured to encode a matrix of weights. A digital to analog convert (DAC) is coupled to the periphery of the tile. The DAC is configured to encode an input vector to voltage pulses applied on the crossbar. An analog to digital converter (ADC) is coupled to a periphery of the tile. The ADC includes a counter. The ADC is configured to measure an induced current on each column of the crossbar and digitize the induced current into a digital value, contained in the counter. A programmable logic controller is coupled to the tile, the DAC, and to the ADC. The programmable logic controller is configured to perform a first MVM integration on a first tier of the first tile. A first partial vector result is obtained from the first MVM integration performed on the first tier and retained in the counter of the ADC. A second MVM integration is performed on a second tier of the first tile. The second result is accumulated with the first result as the second result is being digitized by the ADC. At the end of the second MVM integration the counter contains the accumulated result of the two integrations. As will be appreciated, the multiple tiers and programmable logic are able to provide MVM operations with large matrices in-situ of the system. The need to access other computer memory or hardware becomes null. Thus, computing time and the usage of other computing resources is substantially reduced.

According to one embodiment, which can be combined with one or more previous embodiments, the programmable logic controller is configured to determine whether a size of the matrix of weights in an input dimension is larger than a capacity of the crossbar in the input dimension, and configures the ADC to aggregate the first result with the second result based on the size of the matrix of weights in the input dimension being larger than the capacity of the crossbar in the input dimension. This feature also allows large matrices to be processed in a tile in-situ without having to send portions of the matrix to different hardware components.

According to one embodiment, which can be combined with one or more previous embodiments, the AIMC system includes a second tile, including a third tier and a fourth tier. The programmable logic controller is further configured to determine whether a size of the matrix of weights, in an input dimension and in an output dimension, is larger than a capacity of the crossbar in the input dimension and in the output dimension. Upon determining that the size of the matrix of weights in the input dimension and in the output dimension is larger than the capacity of the crossbar in the input dimension and in the output dimension, the programmable logic controller determines whether to aggregate or concatenate MVM integrations results from the first tile with the second tile. This feature accounts for handling partial results in a tile when the matrix is larger than the crossbar in a tier can handle.

According to one embodiment, which can be combined with one or more previous embodiments, upon a determination that input vectors arrived faster than the time to execute the single integration, the programmable logic controller configures the ADC to aggregate the first result with the second result. The aggregated result is represented as the counter value in the register of the ADC. The programmable logic controller forwards the counter value to the second tile. The programmable logic controller resets the counter value in the register of the ADC. The programmable logic controller performs a third MVM integration on the third tier. The programmable logic controller obtains a third result from the third MVM integration performed on the third tier. The programmable logic controller performs a fourth MVM integration on the fourth tier. The programmable logic controller obtains a fourth result from the fourth MVM integration performed on the fourth tier. The programmable logic controller configures the ADC to aggregate the third result with the fourth result. The aggregated result of the third result and the fourth result is represented as a new counter value in the register of the ADC. This feature speeds up processing of partial results by retaining counters within a tile at the expense of adding more hardware space in the register area and more complexity to the local controller's code.

According to one embodiment, which can be combined with one or more previous embodiments, the programmable logic controller is further configured to upon a determination that input vectors arrived slower than the time to execute the single integration, the programmable logic controller loads a first input dimension input vector to a DAC register. The programmable logic controller performs the first MVM integration on the first tier of the first tile. The programmable logic controller obtains the first result from the first MVM integration performed on the first tier. The programmable logic controller stores the first result as a first stored counter value in the register of the ADC. The programmable logic controller performs a third MVM integration on the third tier of the second tile. The programmable logic controller obtains a third result. The programmable logic controller stores the third result as a second stored counter value in the register of the ADC. The programmable logic controller loads a second input dimension input vector to the DAC register. The programmable logic controller loads the stored first counter value. The programmable logic controller performs the second MVM integration on the second tier of the first tile. The programmable logic controller stores the second result as a third stored counter value in the register of the ADC. The programmable logic controller loads the second stored counter value. The programmable logic controller performs a fourth MVM integration on the fourth tier. The programmable logic controller obtains a fourth result from the fourth MVM integration performed on the fourth tier. This feature helps process large matrices that exceed the crossbar capacity in both the input and output dimensions by computing the partial results going across the input dimension while the vectors across the output dimension are being waited on.

According to one embodiment, which can be combined with one or more previous embodiments, a first final result of the first tile is concatenated with a second final result of the second tile. As may be appreciated, when dealing with partial integrations for a weight matrix whose vector in the output dimension exceeds the capacity of the crossbar, the partial results across different tiers cannot be simply added together. The device in this instance is programmed to stitch the partial results together which would represent an accurate result.

According to one embodiment, which can be combined with one or more previous embodiments, the AIMC system also includes a configurable switch coupled to the programmable logic controller. The configurable switch is programmed by the programmable logic controller to select a counter value from the register of counters used in a current MVM integration operation. The configurable switch alleviates the overhead that context interleaving can generate by bringing the temporary memory closer to the ADC itself by changing the design to have multiple counters (bank of counters) and a configurable switch to choose the counter that is going to be augmented in the current integration.

According to one embodiment, which can be combined with one or more previous embodiments, the AIMC system also includes a down-sampling module coupled to the programmable logic controller. The down-sampling module is configured to reduce a number of voltage pulses by a discrete frequency. Down-sampling in the current context may be useful to reduce the number of bits stored in the counter (thus reducing the space required for a register), at the expense of accuracy in the results.

According to one embodiment, which can be combined with one or more previous embodiments, the AIMC system also includes a configurable switch coupled to the programmable logic controller. The configurable switch is programmed by the programmable logic controller to select a counter value from the register of counters used in a current MVM integration operation. The down-sampling module is disposed to provide the reduced number of voltage pulses, from a programmed input number of voltage pulses, to the configurable switch. The features here provide flexibility in the computational scheme by allowing the controller to select which counter value to use next, thereby alleviating some downtime when waiting for a vector input to arrive. Simultaneously, the number of bits stored in the counter are reduced at the expense of accuracy in the results.

According to one embodiment, which can be combined with one or more previous embodiments, the programmable logic controller is configured to use bit-serial input encoding with a sliding window process, in the register of counters in the ADC. Bit-serial input encoding accelerates the integration operation and, in some cases, increase the accuracy. The sliding window approach offers an easy method to successfully do the partial result accumulation across tiers, while the ADC is also performing the partial result accumulation for each input bit.

According to one embodiment, which can be combined with one or more previous embodiments, the programmable logic controller is configured to use bit-serial input encoding with a bit right shift process, in the register of counters in the ADC. The right shift approach saves register space since a bit is dropped for each increment.

According to one embodiment, which can be combined with one or more previous embodiments, the programmable logic controller is configured to map a convolutional layer across multiple tiers of multiple tiles. Traditionally, convolutional layers are processed by going back and forth between a tile and the peripheral elements, which takes a significant amount of time and resources in the back and forth. By mapping the convolutional layer across multiple tiers, the processing for a convolutional neural network can be accomplished in-situ, minimizing forwarding data back and forth between the tile and peripheral elements.

According to an embodiment of the present disclosure, an analog in-memory computing (AIMC) system is disclosed. The AIMC includes a plurality of tiles. A plurality of vertically stacked tiers are present on each tile. Each tier comprises a crossbar of resistive memory devices on each tier, including a plurality of columns, wherein the crossbar is configured to encode a matrix of weights. A digital to analog convert (DAC) is shared by the plurality of tiles. The DAC is configured to encode an input vector to voltage pulses applied on the crossbar. An analog to digital converter (ADC) is shared by the plurality of tiles, and includes a register of counters. The ADC is configured to measure an induced current on each column of the crossbar and digitize the induced current into a digital value. A programmable logic controller is coupled to the plurality of tiles, the DAC, and to the ADC. The programmable logic controller is configured to: control the ADC to retain integration values between integrations performed for each tier. An accumulation of partial integration results is performed in-situ of the tile. As will be appreciated, the multiple tiers and programmable logic are able to provide MVM operations in-situ of the system. The need to access other computer memory or hardware becomes null. Thus, computing time and the usage of other computing resources is substantially reduced.

According to one embodiment, which can be combined with one or more previous embodiments, the programmable logic controller is configured to aggregate partial integration results of tiers on a same tile. This feature helps process large matrices in a tile in-situ without having to send portions of the matrix to different hardware components.

According to one embodiment, which can be combined with one or more previous embodiments, the programmable logic controller, upon determining that an output dimension of the matrix of weights exceeds a capacity of the crossbars of resistive memory devices, is configured to concatenate partial results from a first tier with partial results of a second tier. This feature provides accurate results while permitting integration of vectors that cannot traditionally simply be aggregated together.

According to one embodiment, which can be combined with one or more previous embodiments, the AIMC system also includes a configurable switch coupled to the programmable logic controller. The configurable switch is programmed by the programmable logic controller to select a counter value from the register of counters used in a current MVM integration operation. The down-sampling module is disposed to provide the reduced number of voltage pulses, from a programmed input number of voltage pulses, to the configurable switch. The features here provide flexibility in the computational scheme by allowing the controller to select which counter value to use next, thereby alleviating some downtime when waiting for a vector input to arrive. Simultaneously, the number of bits stored in the counter are reduced, at the expense of accuracy in the results.

According to one embodiment, which can be combined with one or more previous embodiments, the programmable logic controller is configured to use bit-serial input encoding with a sliding window process, in the register of counters in the ADC. The sliding window approach offers an easy method to successfully do the partial result accumulation across tiers, while the ADC is also performing the partial result accumulation for each input bit.

According to one embodiment, which can be combined with one or more previous embodiments, the programmable logic controller is configured to use bit-serial input encoding with a bit right shift process, in the register of counters in the ADC. The right shift approach saves register space since a bit is dropped for each increment.

According to one embodiment, which can be combined with one or more previous embodiments, the programmable logic controller is configured to map a convolutional layer across multiple tiers of multiple tiles. Traditionally, convolutional layers are processed by going back and forth between a tile and the peripheral elements, which takes a significant amount of time and resources in the back and forth. By mapping the convolutional layer across multiple tiers, the processing for a convolutional neural network can be accomplished in-situ, minimizing forwarding data back and forth between the tile and peripheral elements.

According to an embodiment of the present disclosure, a programmable logic controller in an analog in-memory computing (AIMC) system is disclosed. The programmable logic controller includes instructions configured to control an analog to digital converter (ADC) coupled to a multi-tier tile, to retain integration values between integrations performed for each tier in the multi-tier tile. The programmable logic controller performs an accumulation of partial integration results in-situ of the tile. By retaining integration values between integrations, MVM operations can be performed for matrices that exceed the crossbar capacity of tiles/tiers. Since the crossbar elements share the same peripheral resources, retaining integration values allows different tiers or tiles to be used to handle the same matrix array of weights without the need to use computing hardware outside of the AIMC system.

### Example Architecture

According to an embodiment of the present disclosure, a programmable logic controller in an analog in-memory computing (AIMC) system is disclosed. The programmable logic controller includes instructions configured to control an analog to digital converter (ADC) coupled to a multi-tier tile, to retain integration values between integrations performed for each tier in the multi-tier tile. The dataflows that programmable logic controller enables allow for accumulation of partial integration results in-situ of the tile.

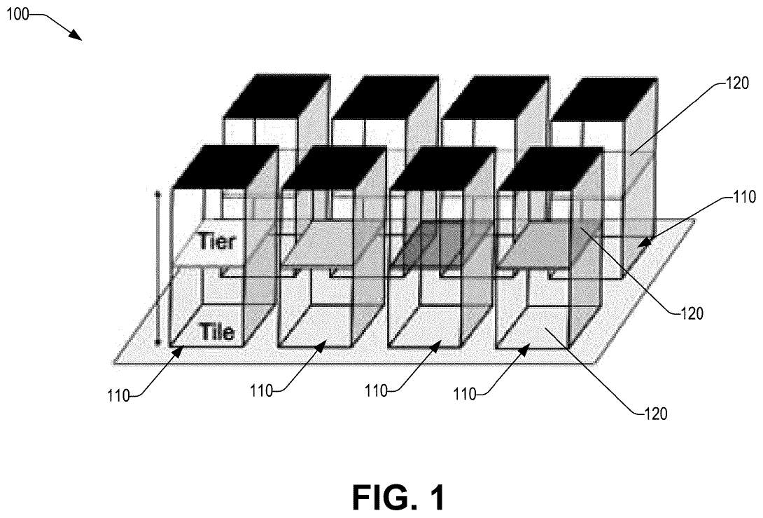

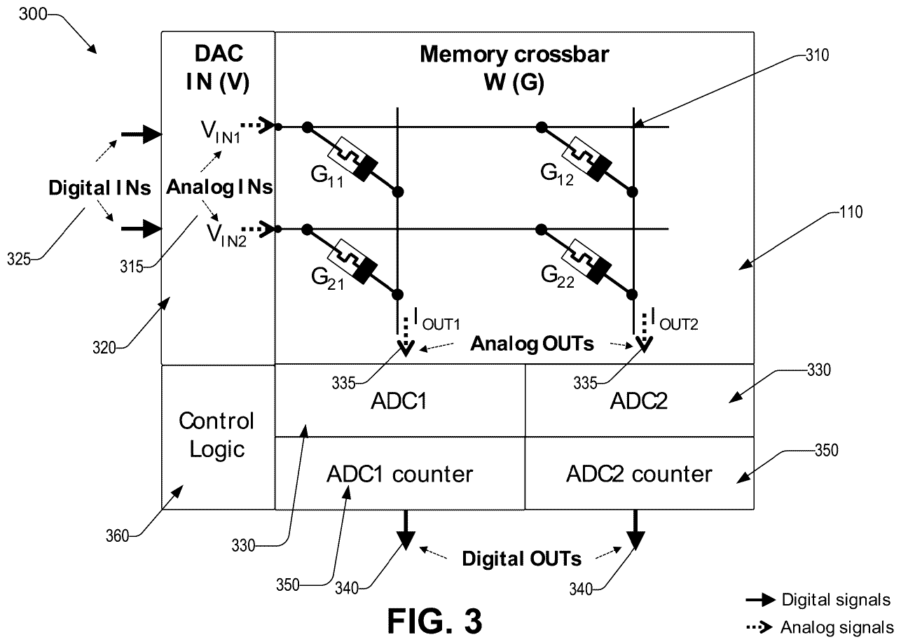

FIG. 1 shows an example representation of a tile array 100 in a 3D AIMC device (sometimes referred to as a “multi-tier AIMC device”). In a 3D AIMC system, 3D AIMC tiles 110 contain multiple tiers 120 of vertically stacked crossbars, that share the same periphery structures (DACs, ADCs, etc.) (the relationship of which can be seen in FIG. 3), but typically operate in a mutually exclusive way. To reiterate, each tile 110 has multiple tiers 120. In this regard, the tiers 120 have their own crossbar arrays. Accordingly, instead of having a single array of devices, multi-tier tiles 110 may have multiple crossbar arrays stacked on top of each other. However, since each tier 120 shares the same periphery resources, the tiers 120 typically cannot operate in parallel. Thus, even though there may be the capacity to operate multiple tiers 120, a multi-tier AIMC device may only operate one tier 120 at a time depending on the tier 120 that is currently accessing the periphery structures. So, there is a challenge in the parallelism: while there is more physical capacity, there is not more computational parallelism.

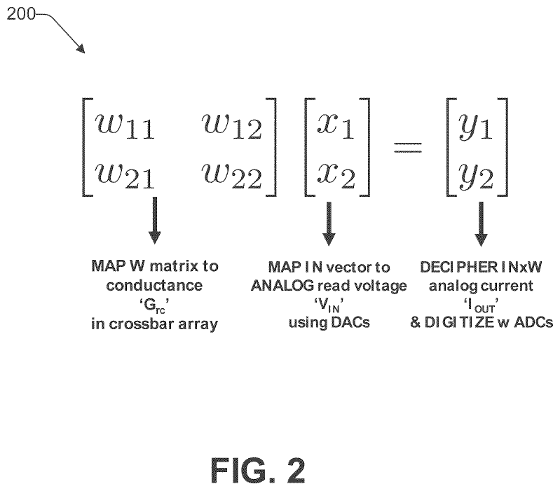

AIMC is better at handling voluminous data and can be used for example, with deep neural networks. An example of an operation that is accelerated using AIMC is the matrix vector multiplication (MVM). FIG. 2 shows an example matrix vector multiplication operation 200. FIG. 3 shows an example schematic of an AIMC system 300 for processing an analog MVM operation. The MVM operation is very important because it is used in many of the machine learning operations of today. The MVM is commonly the largest workload of artificial intelligence and of other optimization problems. AIMC can be power efficient because data does not need to be moved. For example, matrix parameters may be used to evaluate data. By encoding the matrix parameters in the conductance of memory elements and applying voltage pulses encoding the vector, Ohm's and Kirchoff's laws may be exploited to calculate dot products by measuring the produced currents. Resistances are in the crossbar 310. We have voltage pulses as an input 315. Using circuit loads, the dot products in the current may be calculated. Applying voltage to some resistors produces currents that accumulate. More dot products result, which as a quantity can be quantified as the MVM. The columns in a matrix represent the currents as the MVM result. The preceding description is the analog way of generating an MVM operation.

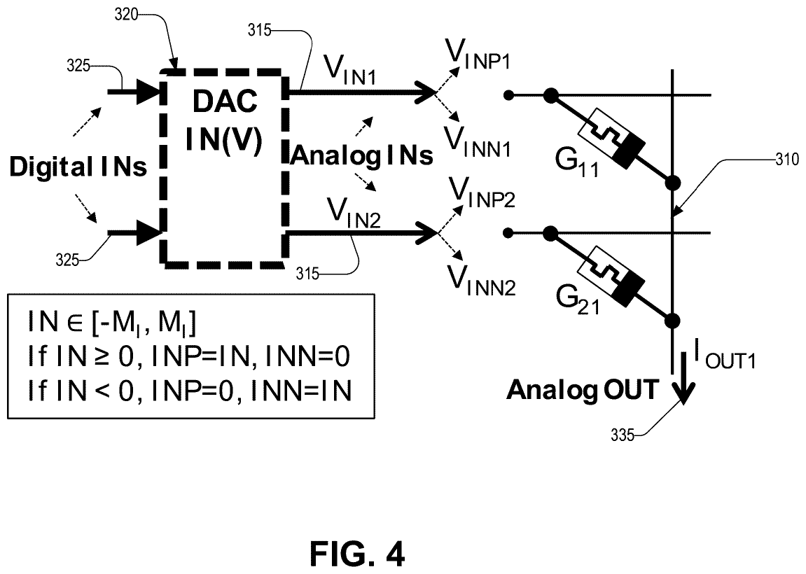

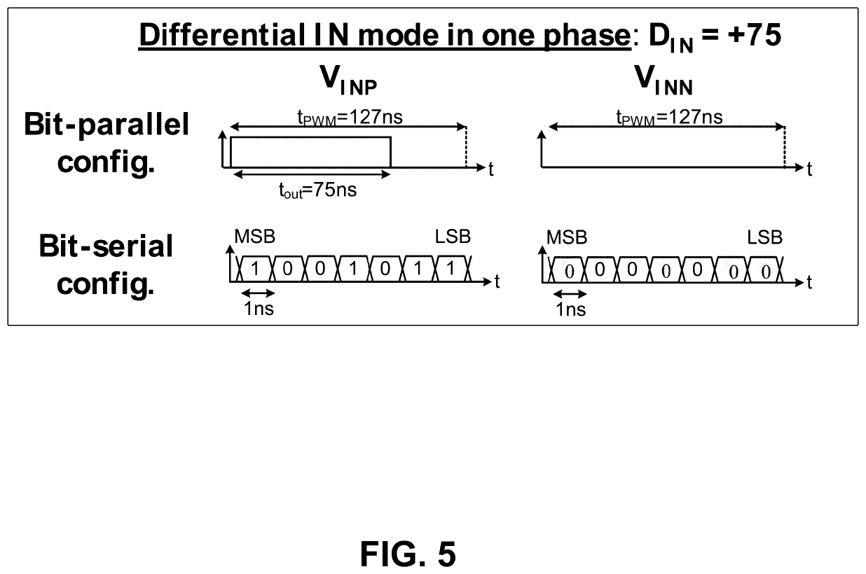

The AIMC system 300 includes one or more tiles 110, which usually comprises three basic elements. One element in the tile 110 is a crossbar 310 of resistive memory devices that will encode the matrix elements of the operation. In the AIMC circuit 300, only a single “tier” of the tile 110 is shown, but it should be understood that multiple tiers of the crossbars 310 stacked vertically over the crossbar 310 shown are present, each crossbar 310 sharing the periphery elements in the following description. Another element in the tile 110 is a series of Digital-to-Analog Converters (DACs) 320 that encode the input vector 325 to the voltage pulses (input 315) that are applied on the crossbar 310. A third element in the tile 110 is a series of Analog-to-Digital Converters (ADCs) 330 that measure the induced current 335 and digitize the current into digital outputs 340, which may be saved as partial result values in the subject technology, within ADC counter registers 350. The crossbar 330 is commonly in the middle of the tile 110 architecture. The series of digital to analog converters 320 are present to receive the input 325 in a digital form (for example, a number as a value is input) to generate a voltage pulse (input 315). A circuit performs the analog conversion. FIG. 4 shows an enlarged view of an example input scheme and conversion path for an AIMC system, excerpted from the AIMC system 300 shown in FIG. 3, consistent with an illustrative embodiment. Then, the analog input is applied on the crossbar. FIG. 5 shows two examples of input configurations that can be used in an AIMC system 300. The input (IN) activation can be represented in two ways (i.e., here, the amplitude of V_{IN}* is either V_{DD} or GND). In the subject technology, the AIMC system 300 includes a programmable logic controller 360 that is configured to control the computation of the input 325 from a matrix of weight values, by the multiple tiers of crossbars 310. Embodiments disclose multiple processes of computing matrices of weight values that are performed in-situ of the AIMC system 300. The embodiments avoid transmitting computational actions outside of AIMC system 300, thus avoiding performing computations back and forth between the AIMC system 300 and external hardware elements, which increase processing time and expend hardware resources outside of the AIMC system 300.

In one approach, a bit-parallel configuration is used that uses pulse-width modulation (PWM). The memory cells are enabled for a duration proportional to IN magnitude and the unit delay is depended on the IN bits. In a bit-serial configuration, there is a multi-cycle read, each with a unit delay duration, where the maximum number of pulse cycles is determined by the IN bits. Each cycle has a V_{IN} value of V_{DD} and GND for data bit 1 and 0, respectively. The currents that are produced on the crossbar are directed into an analog to digital converter. The ADC takes the current and creates a digital value out of the current. In a sense, the whole block (tile) is a digital-to-digital process. When a digital number is input, the tile generates a digital output; but, in the meantime, there are the two conversions that occur, which include converting the input from a digital value to an analog. There is a matrix of elements as analog values. Multiplication occurs in the analog domain. When the result is produced in the analog domain, the result is converted to a digital value.

A key challenge of AIMC systems in general, is that the required periphery occupies similar, or even more, area than the crossbar array. The periphery structures in a tile (for example, the local digital processing unit, the DAC, and the ADC) perform a lot of the conversion processes. The periphery structures may use a majority of the tile footprint and consume much of the tile's energy to perform the conversions. Typically, the periphery structures are the main source of energy consumption in a tile. So, many AIMC architectures try to relieve the strict area and efficiency constraints by multiplexing the outputs from their periphery structures. In some approaches, full-parallel operation elements themselves are sacrificed as a result. For example, an architecture may use a 256 by 256 array in the cross-bar. Thus, 256 ADC processes are used. But some approaches use less ADC converter elements but use the converters twice or three times. So instead of doing one operation at the same time, the multiplexing approach does two or three steps so they sacrifice parallelism to get more efficiency out of the same area used.

Another key challenge for AIMC, is the weight capacity parameter (used for deep neural networks). A “weight” as used herein refers to a value applied to inputs. The “weight” may be a number encoded into for example, resistance in the tile. When voltage is applied to the cross-bar, the output is affected by the weight for that pulse. In AIMC tiles, there is a weight stationary architecture, where all weight values of a network have to be in the system (i.e., encoded) prior to operation. One cannot reload weights as can be done, for example, on a GPU or on a CPU. Reloading weights may have a high computational overhead. In the state-of-the-art for deep neural networks, tens of millions to billions of weight parameters may be used. So, as may be understood, there is a challenge for weight stationary systems to fit so many parameters in the same physical space without moving data around. The subject technology herein addresses the challenges described above by using 3D (or multi-tiered) memory technology in AIMC system.

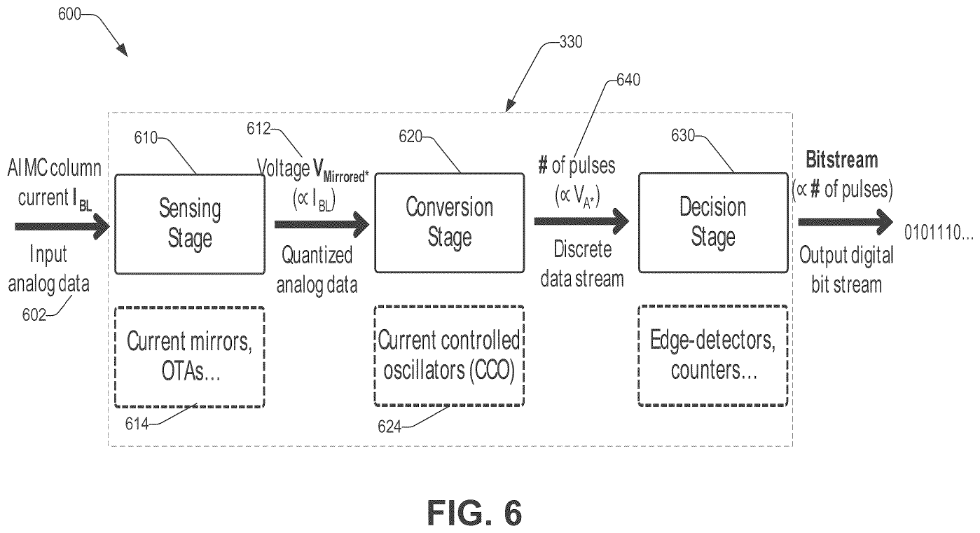

FIG. 6 shows an example of an analog-to-digital conversion process 600 for the AIMC system 300, consistent with an illustrative embodiment. The ADC 330 block is typically the structure that dominates the efficiency and the accuracy of the in-memory computing operation. With the signals within the crossbar array 310 being analog, there are analog conductances in the crossbar arrays 310 and weights are encoded in these conductances. In practice, one applies analog voltage pulses to the AIMC system 300 creating analog currents. The ADC 330 block converts the analog current back to the digital domain such that data may be sent around to different units, as well as to perform digital computations on the data. The ADC 330 block typically includes three stages, and the purpose of the ADC 330 is to provide a linear response to the input. The first stage is usually a sensing stage 610. The sensing stage 610 ensures that a linear value reaches the ADC as analog input (IBL) ∝ 612 ideal equivalent analog MVM value. In the sensing stage 610, the current of the of the crossbar is received as input analog data 602. In current-based ADCs, the sensing stage 610 includes current mirrors, OTAs, etc., (614) and provides an intermediate analog workable conversion value to the next stage. The conversion stage 620 converts the intermediate analog value to discrete quantities that is then fed into the last stage (i.e., decision stage 630). The magnitude of the current is converted to a frequency for a data set. The conversion stage 620 also includes compensation blocks to address any non-linearities of this block. In current-based ADCs, the conversion stage includes a current-controlled oscillator (CCO) 624, which receives the mirrored current from the sensing stage 610 and generates spikes or pulses ∝ IBL. In the conversion stage 620, discretization happens. The analog value is used to create a stream of discrete data. For example, taking a current value, an intermediate representation is created. The current value is then converted to a train of pulses 640. The size of the current is encoded on the frequency of these pulses. By way of example and not limitation, one pulse is generated every 10 nanoseconds. Now, if there is twice the number of pulses generated, the signal should be created with double the frequency (i.e., every five nanoseconds should have a new pulse). The decision stage 630 counts the number of pulses generated by the CCO 624 as a digital output. The decision stage 630 measures how many pulses are received over a given time. To measure how many pulses are received by the previous stage, the decision stage may include edge-detectors to understand when the pulse goes from high to low and from low to high and a counter to count how many transitions of interest are detected with the edge detectors (e.g. how many low to high transitions are witnessed.

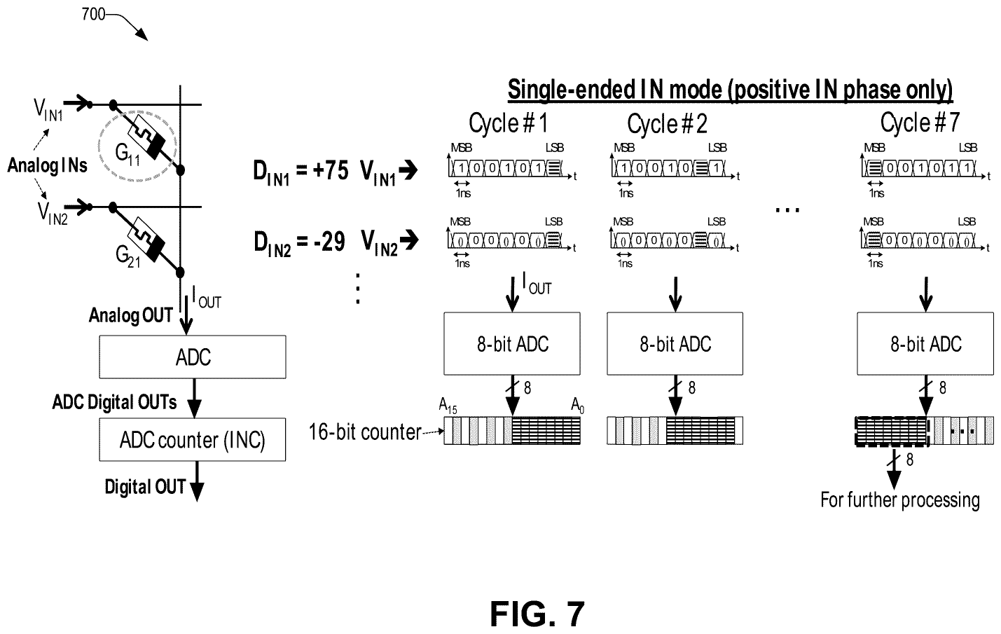

FIG. 7 shows a diagram 700 illustrating post-processing of ADC bits, consistent with an illustrative embodiment. In bit-serial mode, 1-bit is provided to V_{IN} in each cycle, for example, from LSB (least significant bit) to MSB (most significant bit). In each of these cycles, an 8-bit ADC output is produced and is collected in an increment counter (INC). For the current illustration, one may assume a size of the increment counter is 16-bit and bits are A15-A0. The significance of the IN bits is typically taken care of by shifting a group of 8-bits that are selected to be incremented. With each step from LSB to MSB, selected bits for incrementing are shifted by one (implying a scaling by a factor of x2). For instance, for IN (LSB): counter bits A7-A0 are incremented; for IN (LSB+1): A8-A1 are incremented; and for IN (MSB): A14-A7 are incremented. A15 is generally kept in case there is an overflow. As shown in the diagram, the incrementation shifts the updated bits from right to left. Bits required for further processing are generally much less than 16-bits (for example, are in the range of 8-bits for A.I. applications). In a case for A.I., the most significant 8-bits of the counter (A15-A8) are propagated further and (A7-A0) are discarded.

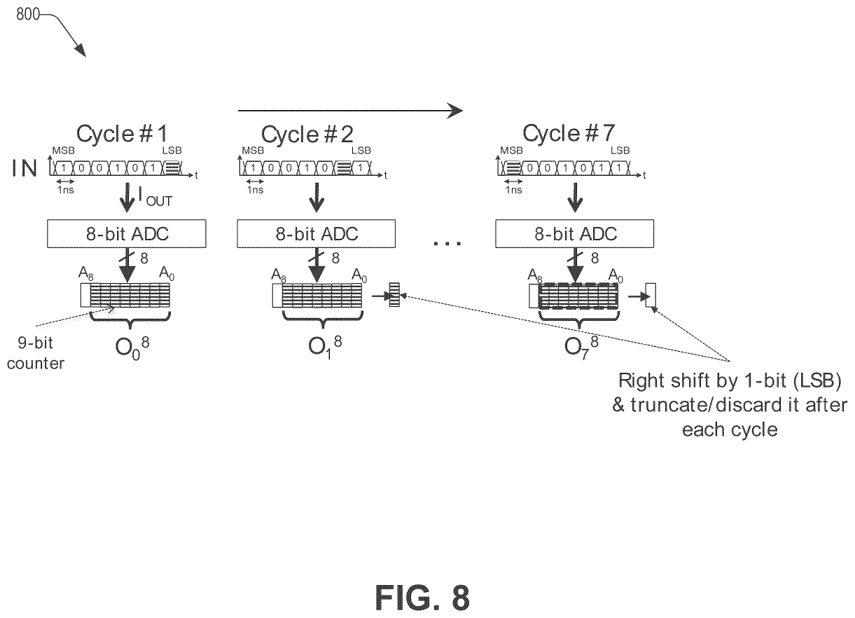

FIG. 8 shows another post-processing example 800 for ADC bits, consistent with an illustrative embodiment. The post-processing method of ADC bits shown in FIG. 8 follows the scheme described above in FIG. 7, but the difference shown in FIG. 8 focuses on reducing the counter size. The IN-bit significance is taken care of by right-shifting and truncating the LSB in each cycle. Using the process in FIG. 8, reduces the size of the counter from (m+n)-bit to essentially (m+1)-bit.

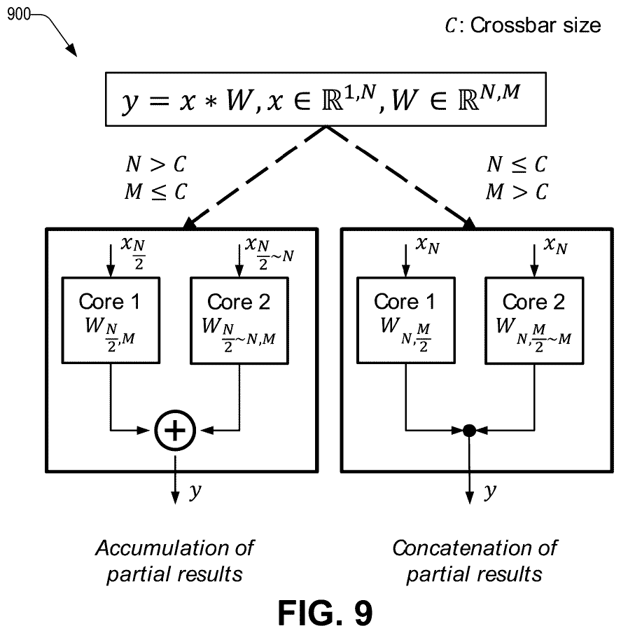

Referring now to FIG. 9, an example 900 of mapping weights to crossbars in a tile is shown, consistent with an illustrative embodiment. A common occurrence when mapping weights to AIMC crossbars is that the size of the array does not fit exactly on one tile. Once the array size capacity is determined for a crossbar, the size does not change. If the weight array is smaller than the size of the crossbar, the tile utilization will be reduced, which leads to reduced efficiency. This case does not cause changes to the dataflow of the system though. If the weight array is larger than the size of the crossbar, the array may be split in multiple crossbars. This split introduces processing steps to combine the partial results. Such processing steps include accumulation and concatenation. Accumulation of partial results is an explicit operation that is added to the network graph after the network is mapped to tiles. Concatenation may be implicit and, thus, is usually less problematic. So, for an application where an MVM is being processed, when the weight array exceeds the array size, the subject technology applies the following conditions to process the input:

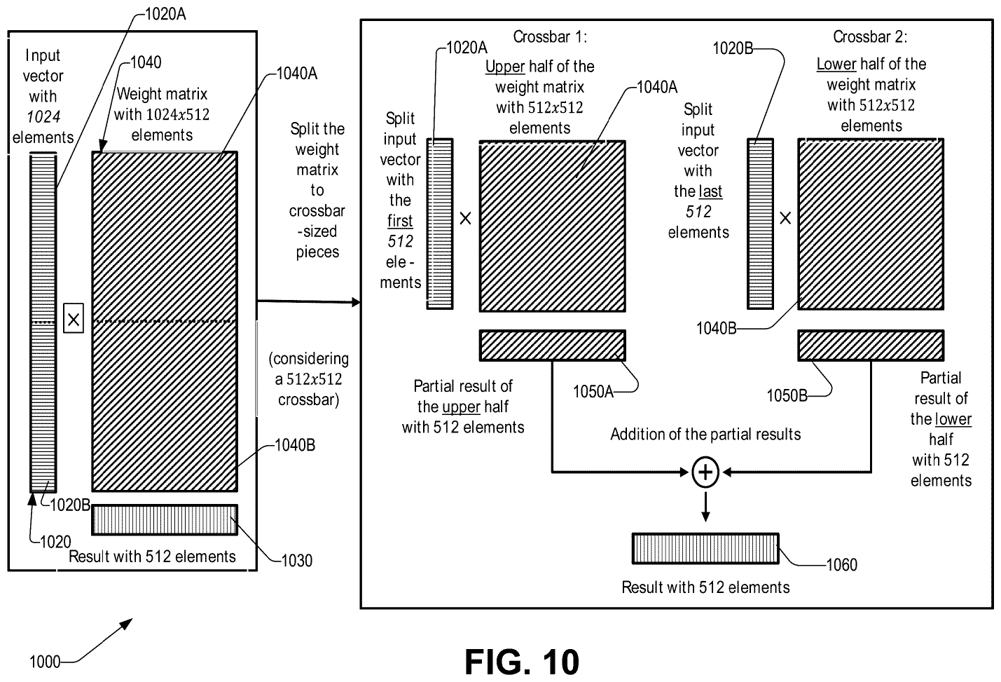

If the weight array is bigger than the size of the crossbar in the input (row) dimension, the layer is split on multiple tiles and the partial results may be accumulated. FIG. 10 shows an illustration where the weight array 1040 (interchangeably referred to as the “weight matrix 1040”) is bigger than the size of the crossbar in the input (row) dimension. In the example 1000 of FIG. 10, the crossbar capacity is 512 elements. The input vector 1020 includes 1024 elements. The output dimension 1030 is 512 elements (which is the capacity of the crossbar). The weight matrix 1040 is 1024 by 512 elements. To process the input vector 1020, the input vector 1020 is split into two (or more) partial input vector parts 1020A and 1020B (which may be evenly split) and sent to different tiles. The partial input vector parts 1020A and 1020B are no larger than the crossbar capacity in the input dimension. In the example shown, the input vector 1020 is split into two parts of 512 elements which is the capacity (size) of the crossbar. Since the input vector 1020 is larger in the row dimension, the weight matrix 1040 is split into upper weight matrix section 1040A and lower weight matrix section 1040B.Now an MVM operation may be performed using each part (partial input vector parts 1020A and 1020B) split off from the original input vector 1020 and the upper weight matrix section 1040A and lower weight matrix section 1040B split from the weight matrix 1040. Each partial result 1050A and 1050B represents the multiplicative result performed on its corresponding part split off from the input vector 1020 and weight matrix 1040. To obtain the final result, the two partial results 1050A and 1050B are added together to produce an aggregated result 1060 of 512 elements. As may be appreciated, aggregating the partial results 1050A and 1050B can be considered adding an additional step to the overall data processing. The extra step may contribute to significant overhead when processing large amounts of data and/or processing many parts split off from the original input vector 1020. For every split performed (for example, 2, 3, 4, 5, . . . n), that many accumulations need to be performed, as is represented by the left side of FIG. 9.

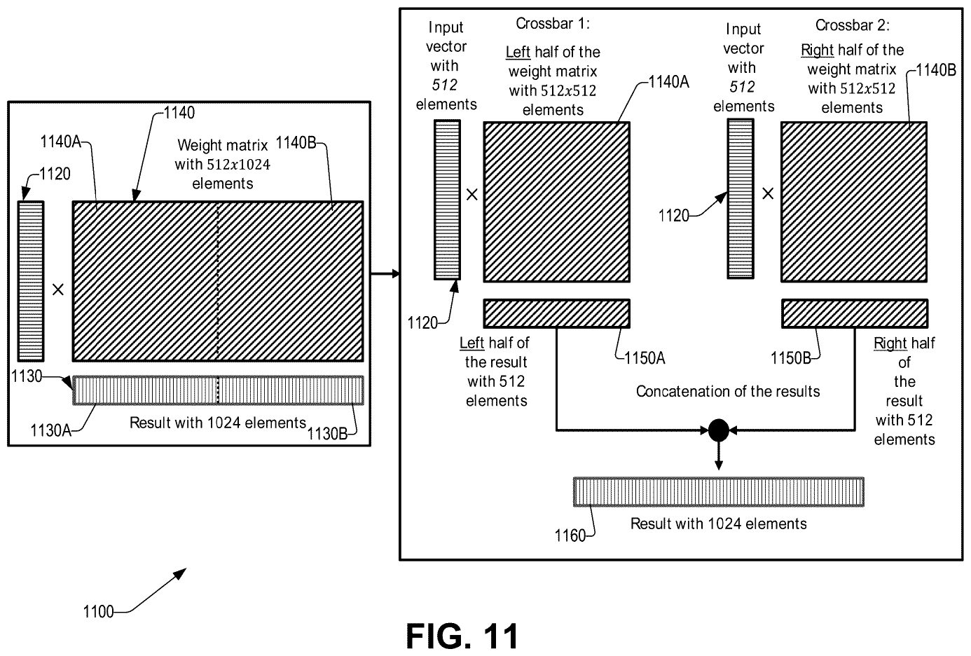

FIG. 11 shows an illustration 1100 where the weight array 1140 is bigger than the size of the crossbar in the output (column) dimension 1130, consistent with an illustrative embodiment. If the array of weight matrix 1140 is bigger than the size of the crossbar in the output (column) dimension 1130, the layer is split on multiple tiles and the partial results may be concatenated. In the example of FIG. 11, the crossbar capacity is 512 elements. The input vector 1120 includes 512 elements, which can be handled without concern. But the output dimension 1130 has 1024 elements (which exceeds the capacity of the crossbar in the output dimension 1130). The size of the weight matrix 1140 is 512 by 1024 elements. To process the data, the weight matrix 1140 is split into two (or more) parts 1140A and 1140B (which may be evenly split). The split parts 1140A and 1140B of the weight matrix 1140 are no larger than the crossbar capacity in the output dimension 1130. In the example shown, the weight matrix 1140 is split into two parts of 512 elements which is the capacity (size) of the crossbar. An MVM operation may be performed using the original input vector 1120 and each part 1140A and 1140B of the weight matrix 1140. Embodiments may process the first half (part 1140A) of the weight matrix 1140 first, resulting in left half partial result 1150A. Then the second half (part 1140B) may be processed resulting in right half partial result 1150B. The final result 1160 may be generated by concatenating (stitching together), the two partial results 1150A and 1150B together. The process is represented by the right side of FIG. 9.

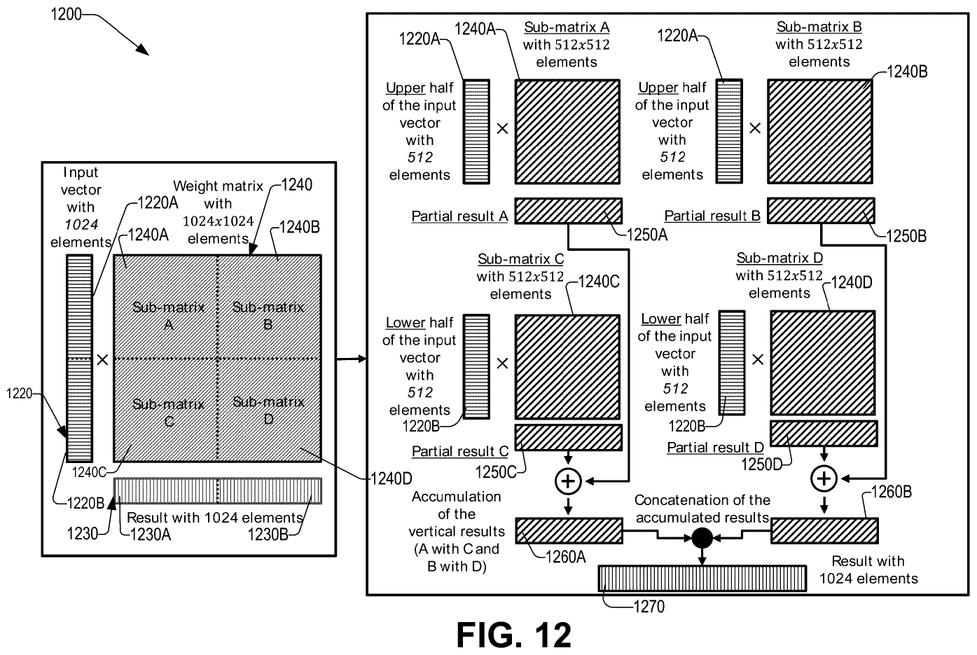

FIG. 12 shows an illustration 1200 where the weight array 1240 is bigger than the size of the crossbar in both the column and row dimensions. If the weight array 1240 is bigger than the size of the crossbar in both dimensions (input vector 1220/output 1230 or row/column), the layer may split among multiple tiles and some partial results may be accumulated and some others may be concatenated. In the example shown, the input vector 1220 is split into two parts partial input vector parts 1220A and 1220B of 512 elements each. The weight matrix 1240 is divided into four partial weight matrix parts 1240A, 1240B, 1240C, and 1240D of 512 elements each. While the example shows four sub-matrix combinations with the input vector parts, it should be understood that the number of sub-matrices for any given computation will depend on the size of the weight matrix 1240 which is ideally evenly split. In the example shown, the partial result 1250A from partial input vector part 1220A (the upper half portion of the input vector 1220) and the partial weight matrix part 1240A (the upper left portion of the weight matrix 1240 (sub-matrix A)) may be accumulated with the partial result 1250C that results from partial input vector parts 1220B (the lower half portion of the input vector 1220) and partial weight matrix part 1240C (the lower left portion of the weight matrix 1240 (sub-matrix C)). The partial result 1250B that results from partial input vector part 1220A (the upper half portion of the input vector 1220) with partial weight matrix part 1240B (the upper right portion of the weight matrix 1240 (sub-matrix B)) may be accumulated with the partial result 1250D that results from partial input vector parts 1220B (the lower half portion of the input vector 1220) with the partial weight matrix part 1240D (the lower right portion of the weight matrix 1240 (sub-matrix D)). The accumulated results 1260A associated with sub-matrices A and C may be concatenated with the accumulated results 1260B associated with sub-matrices B and D to generate final result 1270.

As may be inferred from the above description of processes, any time that a computational step is used across multiple tiles, additional communication resources are expended. Efficiency in the AIMC system is lowered. In addition, latency in the AIMC system increases.

In multi-tiered systems, if the layers are mapped on the same tile, consideration should be given that the generated partial results may be stored in a volatile memory (SRAM) until the last in sequence MVM operation is executed. If the unit that performs the accumulation is not in the direct vicinity of the tile, the data may be transferred through the communication channel to the unit. If the succeeding weight array is also in the same tile, the data returns to the vicinity of the tile for the next operation to execute.

In the subject technology, a multi-tier AIMC tile is disclosed enabling faster and resource-efficient AIMC systems. The subject tile more efficiently handles the partial results scenarios when the input data exceeds the crossbar capacity. When the tile receives input that will be handled by splitting up the data into portions generating partial results, the tile is capable of processing the partial results in-situ.

### Example Tile

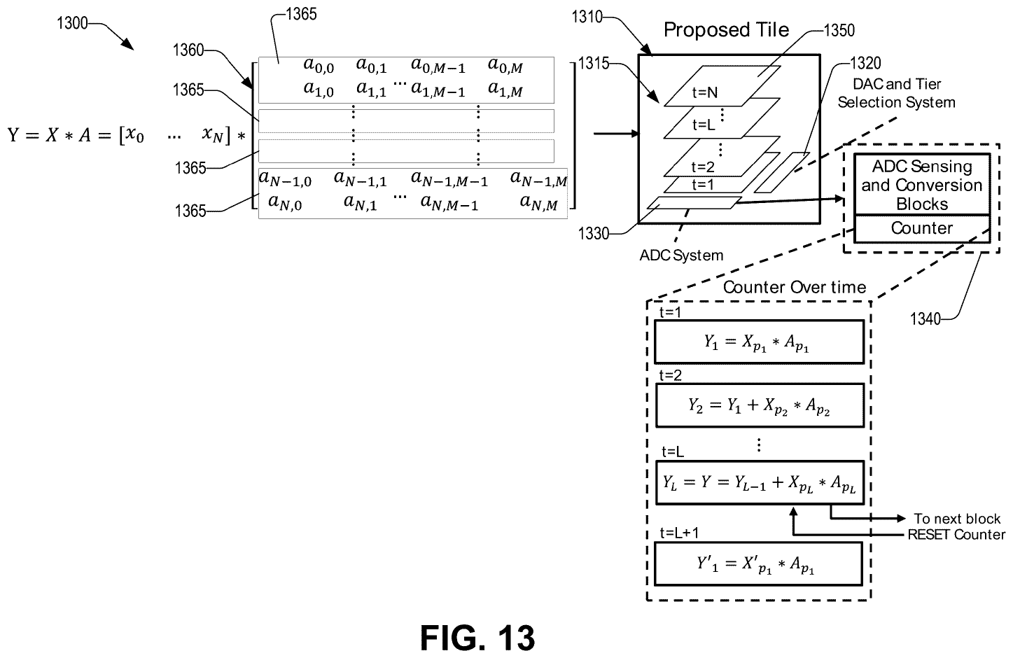

Referring now to FIG. 13, a tile architecture 1300 for AIMC systems is shown according to an embodiment. The tile 1310 includes a three-dimensional crossbar 1315 (represented by the space inside the box for the tile 1310), including multiple (N) tiers 1350 with a crossbar array of size K×M. A Digital-to-Analog Conversion (DAC) periphery circuit 1320 coupled to the crossbar 1315, supports either bit-parallel or bit-serial input encoding or both. An Analog-to-Digital Conversion (ADC) 1330 circuit may be peripheral to the crossbar 1315. The ADC circuit 1330 may include configurable behavior with regards to conversion dataflow. The tile 1310 further includes a programmable local controller circuit 1340 enabling novel dataflows (described in more detail below). The programmable local controller circuit 1340 may be an active component; for example, a reduced instruction set computer processor or a passive finite state machine (FSM) with accompanied configuration registers. The programmable local controller circuit 1340 controls how the ADC conversion will happen. In addition, the programmable local controller circuit 1340 determines when a process calls for parsing input up and computing partial results by either accumulation (sometimes referred to as aggregation), by concatenation (sometimes referred to as stitching) or a combination of both.

The architecture 1300 is shown processing a weight matrix 1360 that exceeds the crossbar capacity. Consider that the proposed tile 1310 with N tiers 1350 has a crossbar size of C×C. The operation to be performed is an MVM between a vector of size K and an array of size K×M. In this example we consider the case that K>C and M≤C, meaning that an accumulation of partial results will be computed to obtain the final result. To process the weight matrix 1360, the weight matrix 1360 may be into multiple sub-matrices 1365 prior to execution time, where the size of each sub-matrix 1365 is within the crossbar capacity. The split may be determined a priori before mapping the weights in the system. The splitting of inputs may be handled by the programmable local controller circuit 1340 as though as the splitting were happening during runtime. For this example, the weight matrix 1360 is four times larger in the input dimension than the capacity of the crossbar.

In the tile 1310, four tiers 1350 are shown but it should be understood that embodiments generally include two or more tiers 1350. For in-situ computation of accumulation results, the respective tiers 1350 may be mapped one of the sub-matrices 1365. For example, for a crossbar whose capacity is 512 elements, the first 512 rows in the bottom sub-matrix 1365 may be mapped to the bottom tier 1350 (“t=1”), the next 512 rows in the next sub-matrix 1365 may be mapped to the second tier 1350 (“t=2”) and so on, until the whole array is mapped to a tier in the same tile 1310. The data mapped may be fit the whole tile or may be less than capacity of the whole tile. Once mapped, an MVM operation may be performed on each tier 1350 generating a partial result.

In the tile 1310, the programmable local controller circuit 1340 enabled by an ADC with configurable integration behavior, enables the following dataflow characteristics. The array is again mapped in L=ceil (K/C) tiers. The programmable local controller circuit 1340 holds that L partial result accumulations are to occur to obtain the final result. The L MVM operations happen sequentially, but the programmable local controller circuit 1340 does not reset the ADC counter between integrations. After L integrations, the final result is in the ADC's counter and the programmable local controller circuit 1340 may move the data for further processing in the next block/tile. The value of the counter is reset for the next set of MVM operations.

As an illustrative example, and still referring to FIG. 13, processing the input may be performed by sequentially computing the matrix multiplication. For example, taking the 1^{st} 512 rows in the bottom tier 1350, the ADC 1330 may convert the current to a digital value. The digital value may be forwarded to the next tile or may be sent away to memory. And the digital value resets. However, one may recall from earlier that since the ADC 1330 process provides a counter value; there is this data stream available where the number of pulses observed may be counted. In one embodiment, the counter function may be modified to instead of resetting every time an MVM is performed, the counter function retains the value. For example, after the first MVM is computed, the result is retained. (Compare to FIG. 6, where after the decision stage 630, the counter is reset before the process restarts at the input to the sensing stage 610). When the second MVM computation is performed, the ADC 1330 starts from the retained value computed for the first MVM computation (instead of zero), and continues to add to the value during the second MVM computation. The programmable local controller circuit 1340 may prevent resetting the counter such that when the full second integration finishes the counter holds the result Y1+Y2. The counter value results continue to accumulate for every tier's MVM computation without resetting until all layers from the matrix 1360 are processed by their respective tiers 1350 in the tile 1310. When the last MVM computation is performed, the counter value represents the final result, which is an accumulation of MVM computations for every tier without resetting the counter. The accumulations occur in-situ within the tile 1310 without moving data around to other tiles and without having to use a separate digital processing unit. Once the final result is obtained, the final result may be forwarded elsewhere in a computing system. The programmable local controller circuit 1340 may reset the process, reset the counter, and may restart a new MVM computation for a new matrix.

### Example Methodology

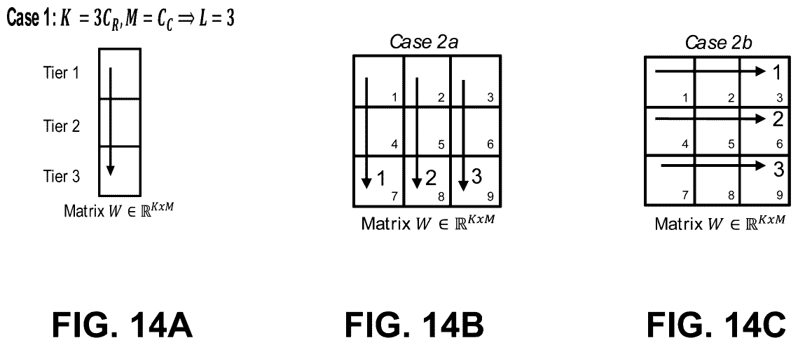

FIGS. 14A, 14B, and 14C show by illustration methods of processing data flow according to embodiments consistent with the architecture 1300 described above. The actions may be performed by the programmable local controller circuit 1340 unless otherwise indicated. In general, the figures show how the programmable local controller circuit 1340 is configurable to handle different input scenarios. Generally, when an MVM operation operates using partial result accumulation, the operation may be accelerated using the tile 1310 as described below. As shown in FIG. 14A, a weight array whose row dimension is equal to three times the tier dimension is considered. In FIGS. 14B and 14C a weight array whose row and column dimensions are three times the tier dimension is considered. According to the conclusions from FIG. 10 and FIG. 12, the partial results from the subarrays depicted in the same column may be accumulated. The number on each square subarray signifies the tier in the tile that the subarray is mapped. All subarrays in this example are mapped on the same tile.

In FIG. 14A, the matrix (size K×M) is larger than the crossbar size (C_{R}×C_{c}) only in the row (input) dimension (K>C_{R} and M≤C_{c}), the dataflow and control signals from the programmable local controller circuit 1340 may be as follows. Accordingly, only rows are being split; not columns. The matrix is mapped in L=ceil (K/C_{R}) tiers. Depending on the sequence of partial inputs arriving from the previous blocks, the integrations may be executed on all L tiers sequentially. Partial inputs may come in any sequence as the accumulation is not affected. The programmable local controller circuit 1340 retains the value of the ADC counter in between the L MVM operations to perform in-situ partial result accumulation. After L integrations are completed, the programmable local controller circuit 1340 moves the accumulated result on to the next block/tile and resets the value of the counter for the next set of operations. For example, as represented by the flow shown in FIG. 14A, the programmable local controller circuit 1340 performs the integration in Tier 1. The partial vector result is retained. The programmable local controller circuit 1340 performs the integration in Tier 2 accumulating values from the result retained from Tier 1. The accumulated result from Tier 2 is retained. The programmable local controller circuit 1340 performs the integration in Tier 3 accumulating values from the result retained from Tier 2. The accumulated result from Tier 3 may be accumulated in the ADC's 1330 Counter values (that contain the accumulated result vector to the next processing block). The programmable local controller circuit 1340 may reset the ADC counter registers.

In FIGS. 14B and 14C, the matrix (size K×M) is larger than the crossbar size (C_{R}×C_{c}) in both the row and column dimensions (K>C_{R} and M>C_{c}), the dataflow and control signals from the programmable local controller circuit 1340 may map the matrix in L=L_{row}*L_{column}=ceil (K/C_{R})*ceil (M/C_{c}) tiers. So, input data will be split in the row dimension, since the tiers in the same row use the same input data. In the example there are only 3 distinct input vectors, one that is consumed by tiers 1, 2, 3, one that is consumed by tiers 4, 5, 6 and one that is consumed by tiers 7, 8, 9. Depending on how the partial input vectors arrive at the tile, the programmable local controller circuit 1340 may operate under one of two scenarios.

FIG. 14B shows how if two consecutive partial input vectors arrive faster than the time it takes to execute a single integration, then the programmable local controller circuit 1340 may perform the MVM along the row dimension first (Case 2a), without the need to manipulate the ADC counter (following the flow presented in Case 1). For example, if the vector values arrive for tier element 1, tier element 4, and tier element 7 in the first tile, substantially simultaneously), the process may generally perform MVM operations for each tier element in the same tile and aggregate the results. For example, the MVM is performed for tier element 1, and then for tier element 4, and then for tier element 7, and the results of each are accumulated into a final result for the tile. Since the input for tier 2 is the same as the input for tier 1, if the three distinct inputs arrive fast enough, the first vertical flow may be prioritized as the first vertical flow is easier to handle from the controller side (no context switches are needed). If though, two consecutive input vectors don't arrive fast enough, the process may continue with tier 2 instead of tier 4 as tier 1 and tier 2 take the same input. In operation, and consistent with the descriptions of FIG. 12, the programmable local controller circuit 1340 may perform operations accumulating results along the columns and may concatenate (stitch) the result of each column to the calculations for the next column. After L_{row} integrations, the programmable local controller circuit 1340 moves the accumulated partial result on the next block/tile and resets the value of the counter so that the next column region can be calculated. For example, the accumulated results of an MVM on tier elements 1, 4, and 7 may be stitched to the result of tier elements 2, 5, and 8, which may be stitched to the result of tier elements 3, 6, and 9. This process may be done L_{column} times in total before starting the next MVM operation.

FIG. 14C shows how if two consecutive input vectors arrive slower than the time it takes to perform a single integration (Case 2b), for example, when an input vector data arrives for tier element 1 but does not arrive timely for tier element 4. An alternative dataflow may be followed to avoid idling while waiting for the next input vector. The programmable local controller circuit 1340 in the instant scenario may start doing the MVM across the column dimension first, as the different column regions receive the same input vector. For example, the MVM is performed for tier element 1, and before moving on to tier element 4, the process performs the MVM for tier element 2, and then tier element 3. In this case, the values for each MVM performed may be stored and then loaded up again when the process returns to the next tier element in the row dimension (for example, the result for tier element 1 is retrieved when performing the MVM for tier element 4). To facilitate that, while still using the in-situ partial result accumulation capability of the ADC, the local controller (programmable local controller circuit 1340) may store the current value of the counter register to a temporary memory and load the value corresponding to the next column region before moving to the next tier (context interleaving). That means that the programmable local controller circuit 1340 has access to some amount of scratchpad memory and that the ADC counter can be read and written by the local controller. After (L_{row}−1)*L_column integrations, the next L_column integrations will produce the fully accumulated result for each column region and the local controller can move them to the next block/tile of the system.

Still referring to FIG. 14C, an example method (performed by the programmable local controller circuit 1340) may include loading a first row region input vector to DAC registers. The MVM integration may be performed in tier element 1. The ADC counter value may be stored and the counter may be reset. The MVM integration is performed in tier element 2 (no input-load needed). The ADC counter value may be stored and the counter may be reset. The MVM integration is performed in tier element 3 (no input-load needed). The ADC counter value may be stored and the counter may be reset. The programmable local controller circuit 1340 may load the input vector for the second row into DAC registers. The ADC counters may be loaded with the values saved from the MVM integration of tier element 1. The MVM integration for tier element 4 may be performed. The new ADC counter value may be stored and the ADC counters may be loaded with the values saved from the MVM integration of tier element 2, and so on until each tier element in the row is processed and the values previously stored from the same column dimension elements are retrieved and processed into the new values before the process continues to the next level of tier elements.

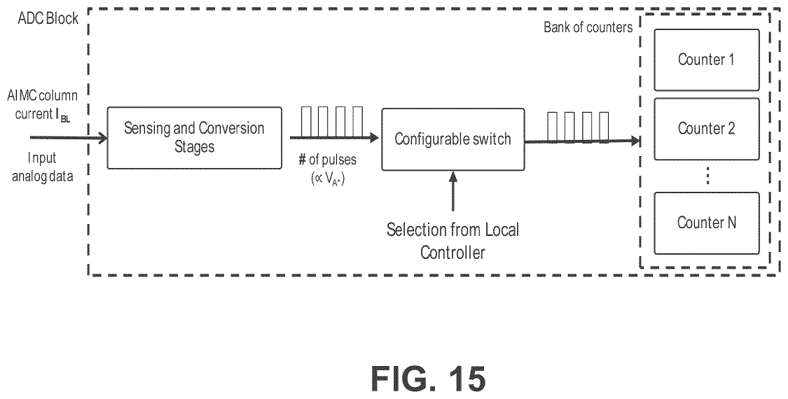

FIG. 15 shows a multi-tier AIMC device for MVM operations with large matrices and for multi-model operation, consistent with an illustrative embodiment. For example, the tile 1310 may be more suited to large matrices (K>C_{R} and M>C_{c}) and to multi-model network mapping in the same unit. Multi-model operation is another way to utilize the weight capacity that is offered by multi-tiered AIMC tiles. In this mode of operation, multiple models co-exist in the same system and an input token can be routed to one or multiple of these models. This mode of operation may increase the need for context interleaving (see case 2b of FIG. 14C), as input vectors of multiple models may arrive in an interleaved fashion, stopping the partial result accumulation flow and necessitating a store operation and a load operation. Furthermore, multi-model operation complicates the instructions that the local controller must execute to realize this dataflow. An embodiment that alleviates the overhead of context interleaving may include bringing the temporary memory closer to the ADC by changing the architecture to have multiple counters (e.g., a bank of counters) and a configurable switch to choose the counter that is going to be augmented in the current integration. The programmable local controller circuit 1340 in that case may change the configurable switch, instead of always executing store-load operations. If the number of counters is less than the necessary context of interleaving steps, a combination of load-stores and counter switches may be employed. So, the programmable local controller circuit 1340 may be programmed to control which tier element is processed next and which counter to retrieve to perform the next MVM operation. For example, and referring back to FIG. 14C, instead of always processing tier element 2 and storing the ADC counter value after processing tier element 1, the programmable local controller circuit 1340 may be pre-programmed to process any other tier element on the tile after tier element 1 is processed. As may be appreciated, the embodiment of FIG. 15 trades additional hardware elements for faster processing.

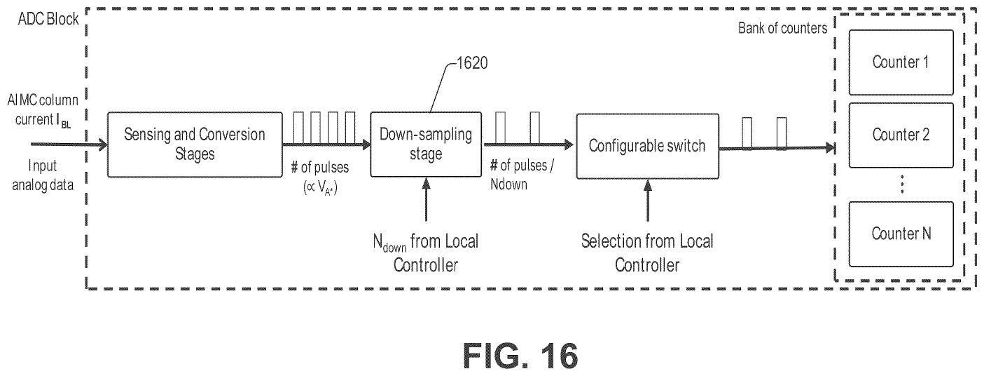

FIG. 16 shows a multi-tier AIMC device for MVM operations similar to the embodiment in FIG. 15 except that the device is configured to reduce precision accumulation of partial results, to save on the bit-size of the counters. As the counter value grows, processing overhead in the register space grows. In this embodiment, a down-sampling stage 1620 is added before the configurable switch, that reduces the number of pulses by a discrete frequency N_{down}. The implementation of this stage may be a separate counter that counts to N_{down}−1 pulses before producing one pulse for the downstream components. The size of this counter may be dependent on the maximum desired down-sampling rate (S=log₂ max (N_{down})). The down-sampling stage allows for a reduction of S-bits from each counter, leading to (S−1)*N total savings in register space. The programmable local controller circuit 1340 may have the option to configure the down-sampling frequency for each counter. This can be calculated a priori based on the number of expected accumulations as follows: Consider an ADC conversion stage that produces up to K-bits per integration and L number of partial-result accumulations for a counter. The number of bits needed to hold the total result without loss of precision is B=K+(L−1) bits. If this number of bits is larger than the size of the counter (B>n), then N_{down} is defined as 2^{(B-n)}. If the dynamic range of each integration is less than K-bits, a lesser number of shifts can be selected for minimal loss. The optimal N_{down} frequency can be found a priori with sample MVMs. It should be appreciated that by down-sampling the number of pulses counted, the number of values in the bank of counters is reduced, thus reducing space overhead in the bank. The tradeoff becomes less space needed for counter values for less precision in the accuracy of results (for example, more quantization error).

### Input Recording Embodiments

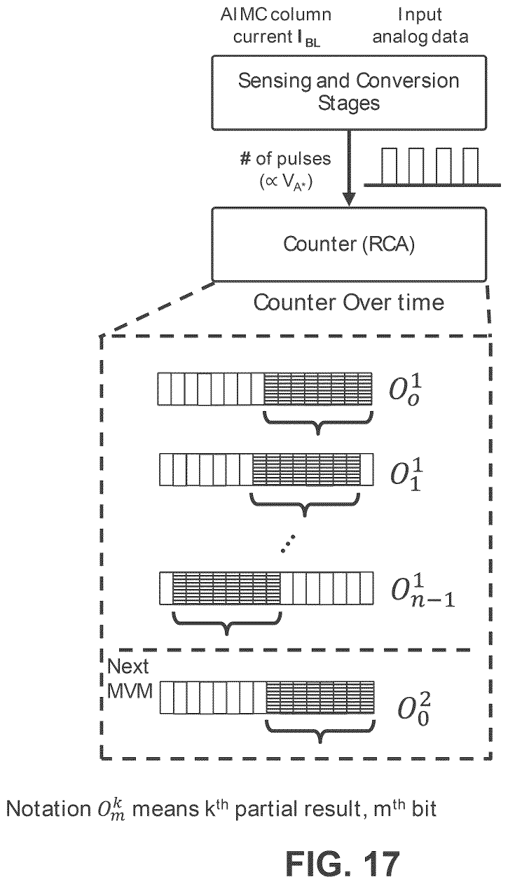

FIG. 17 shows a three-dimensional AIMC device performing MVM operations with large matrices using bit-serial input encoding, incorporating a sliding window approach, according to an embodiment. When performing an MVM integration in an analog way, there are voltage pulses applied to a crossbar and that produce a current. There can be two type of pulses: a single one pulse or multiple pulses right that can be used to encode by its/their value in duration. By way of example and not limitation, if one wanted to apply the number 100 on an input crossbar, a voltage pulse may be applied for 100 nanoseconds. The time dimension encodes the value. Depending on the time applied for the one voltage pulse a value for current can be determined. The values for current are used in the sensing and conversion stage.

Bit-serial input encoding (sometimes also referred to as “bit slicing”) is a way of encoding the value in its frequency (instead of using a single pulse). Multiple pulses may be used depending on the binary representation of the number. For example, when the value is 100, the value has a binary representation. Instead of applying one pulse for 100 nanoseconds, bit slicing will use one bit value to represent that a pulse is on and the other bit value to represent the pulse is off. What occurs is that when the next position of the input occurs, that means that the value is double the value of the previous position. So ‘hat’s the binary representation. So, if the least significant bit, was 2 to the zero power, the next bit is 2 to the one power. The next bit 2 is two the two power, and so on. Now there are different significances which are usually accounted for in the ADC already. If there is an 8-bit input, several multiplications are needed. And then the results are added. However, the device has to account for the fact that each time the result has a different significance because the next input is twice the size of the value of the previous input.

Bit-serial input encoding is an effective method to accelerate the MVM integration operation and, in some cases, increases the accuracy of integration in the subject device embodiments. When bit-serial input encoding is used, the DAC system encodes the value of the input as a series of pulses, one for each bit of the input value. In systems employing bit-serial input encoding, the ADC usually accumulates the partial results created for every cycle. These results have different significance (as described above, differing by a factor of two each time), as each input pulse is also of different significance. Embodiments may incorporate a sliding window approach in the ADC. The counter register is selected to be of size N=k+n, where k is the output size of every integration and n is the number of input bits. For each bit-cycle, only a subregion of the ADC counter is updated. The subregion is selected based on the bit number of the current integration as shown in the figure.

In instant embodiment, we show that the device described in FIGS. 14A-14C can be used even when bit-serial input encoding is employed. The sliding window approach offers an easy method to successfully do the partial result accumulation across tiers, while the ADC is also performing the partial result accumulation for each input bit. The m^{th} bit-cycle of each tier will be added to the same region, thus ensuring an equal significance accumulation across tiers.

ADCS already perform the accumulations in tiles, but with bit-serial input encoding, the accumulation of MVM results may be added directly. For example, an MVM is performed for a tier element. To perform the MVM integration for another tier element down the line, several other MVM integrations need performing along with their partial results. Generally, the partial results are found using something similar to a nested accumulation loop. In embodiments using a sliding window, the counter is modified to shift the value for an MVM integration counter over from where the previous value is counted in a set of bits. For example, as shown in FIG. 17, instead of counting and putting the value on the far right end of the bit value (as shown in the top line of counters), the next MVM integration counter value is counted starting one bit place over to the left (and now ignoring the bit position on the far right end which is now empty). Now that the counter is shifted left, that means it actually doubled the value of what is counted. Each successive partial result shifts the counter value over one additional place when accumulating results until the MVM integration is done for a tier element. When the MVM integration is done, the process restarts and the counter value for the next MVM integration is performed starting from the far right end of the sliding window.

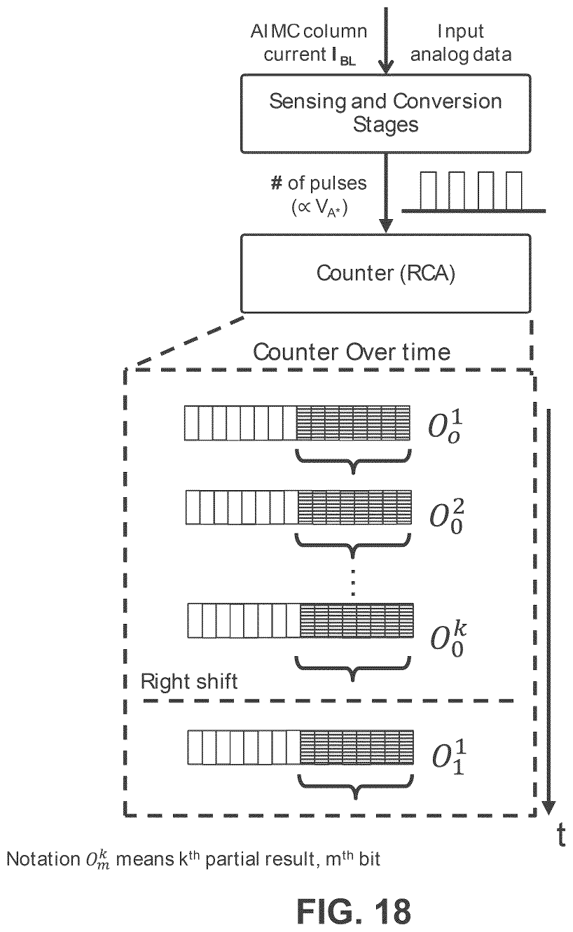

FIG. 18 shows a three-dimensional AIMC device performing MVM operations with large matrices using bit-serial input encoding, and incorporating a right shift approach, according to an embodiment. In this embodiment, bit-serial input encoding is used. As discussed with respect to FIG. 17, the ADCs in systems supporting bit-serial input encoding usually perform partial result accumulation between the results of every cycle. These results are of different significance. The use of the sliding window scheme discussed above is effective but needs a large register to accumulate all the bit-cycles. The counter for the AIMC device in FIG. 18 accumulates the results in reduced precision by shifting right after every cycle integration (for example, as described in the process discussed in FIG. 8). For example, the right-most bit is dropped. The counter value occupies the same bit positions as a new bit is added to the left end of the bits. Right shifting by one bit can work with a register of size N=k+1, where k is the output size of each integration. It should be noted that right shifting may not be amenable to accumulation of results across tiers, since at each cycle, the significance of the number in the counter is changing. But, right shifting saves space in the counter area and is thus economical from the perspective of reducing counter area at the cost of reduced accuracy.

To integrate such a scheme in the proposed device, and perform accumulation across tiers, there needs to be a change in the sequence of performed integrations, configured by the programmable local controller circuit 1340. For k across-tier accumulations and m bit input the method includes performing integration for all k tiers with their respective Oth input bit. Between the integrations, the programmable local controller circuit 1340 operates as described in FIGS. 14A-14C, 15, and 16 (aggregating and concatenating partial results depending on the conditions). The FIGS. 14A-14C, 15, and 16 shifts the partially accumulated counters to the right. The programmable local controller circuit 1340 performs integration for all k tiers with their respective 1st input bit. Again, during these operations the programmable local controller circuit 1340 operates as described in FIGS. 14A-14C, 15, and 16. The process repeats the integration and accumulation of partial results until all m bits are finished.

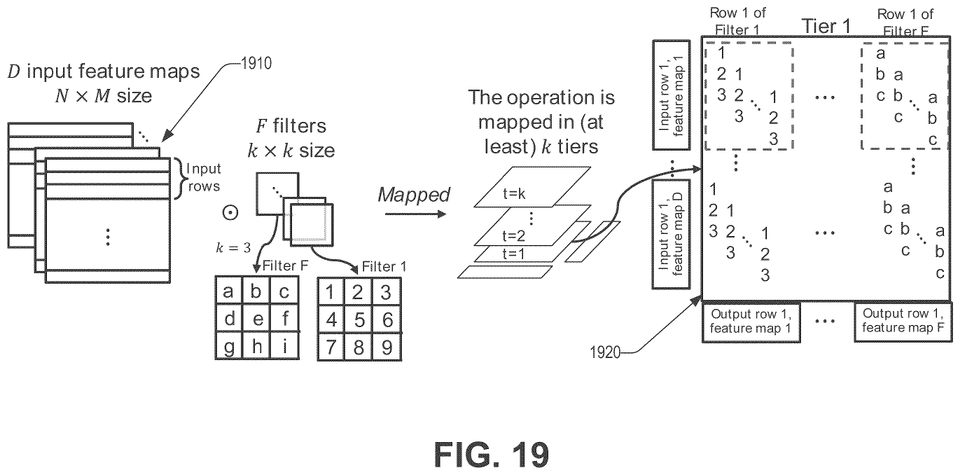

FIG. 19 shows a method of mapping a convolutional neural network using a three-dimensional AIMC device, according to an embodiment. For example, the three-dimensional AIMC device may use a row-by-row process to execute layers of a convolutional neural network (CNN). Part of the computation at each integration cycle may be performed producing a partial result. The partial results are accumulated to produce the final result. The accumulations are performed in the analog domain with the use of integrators. In the subject device, a convolutional layer may be mapped across tiers such that the partial result accumulations needed by the row-by-row process occur in the ADC counters, as in the case of an MVM with a large matrix. In mapping a CNN layer (represented by feature maps 1910), each row of a filter may be mapped transposed to a different tier to facilitate in-situ ADC accumulation of partial results. As the inputs arrive at the tile 1920, the first row of the feature maps gets multiplied by the first tier creating the first set of partial results on the ADC. Then the next row is executed with the second tier and so forth. Every k integration, a row of the output feature maps is created and may be forwarded to the next layer.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

Aspects of the present disclosure are described herein with reference to call flow illustrations and/or block diagrams of a method, apparatus (systems), and computer program products according to embodiments of the present disclosure. It will be understood that each step of the flowchart illustrations and/or block diagrams, and combinations of blocks in the call flow illustrations and/or block diagrams, can be implemented by computer readable program instructions.

These computer readable program instructions may be provided to a processor of a computer, special purpose computer, or other programmable data processing apparatus to produce a machine, such that the instructions, which execute via the processor of the computer or other programmable data processing apparatus, create means for implementing the functions/acts specified in the call flow process and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the call flow and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the call flow process and/or block diagram block or blocks.

The flowchart and block diagrams in the Figures illustrate the architecture, functionality, and operation of possible implementations of systems, methods, and computer program products according to various embodiments of the present disclosure. In this regard, each block in the call flow process or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or call flow illustration, and combinations of blocks in the block diagrams and/or call flow illustration, can be implemented by special purpose hardware-based systems that perform the specified functions or acts or carry out combinations of special purpose hardware and computer instructions.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. An analog in-memory computing (AIMC) system, comprising:
a first tile having two or more stacked tiers;
a crossbar of resistive memory devices on each tier, including a plurality of columns, wherein the crossbar is configured to encode a matrix of weights;
a digital to analog convert (DAC) coupled to a periphery of the first tile, wherein the DAC is configured to encode an input vector to voltage pulses applied on the crossbar;
an analog to digital converter (ADC) coupled to a periphery of the first tile, and including a register of counters, wherein the ADC is configured to measure an induced current on each column of the crossbar and digitize the induced current into a digital value; and
a programmable logic controller coupled to the first tile, the DAC, and to the ADC, wherein the programmable logic controller is configured to:
perform a first matrix vector multiplication (MVM) integration on a first tier of the first tile;
obtain a first result from the first MVM integration performed on the first tier;
perform a second MVM integration on a second tier of the first tile;
obtain a second result from the second MVM integration performed on the second tier; and
accumulate the first result and the second result into an accumulated digital value of the first tile, represented as a counter value in a register of the ADC.

2. The AIMC system of claim 1, wherein the programmable logic controller is configured to:
determine whether a size of the matrix of weights in an input dimension is larger than a capacity of the crossbar in the input dimension; and
aggregate the first result with the second result based on the size of the matrix of weights in the input dimension being larger than the capacity of the crossbar in the input dimension.

3. The AIMC system of claim 1, further comprising a second tile, including a third tier and a fourth tier, wherein the programmable logic controller is further configured to:
determine whether a size of the matrix of weights in an input dimension and in an output dimension is larger than a capacity of the crossbar in the input dimension and in the output dimension; and
upon determining that the size of the matrix of weights in the input dimension and in the output dimension is larger than the capacity of the crossbar in the input dimension and in the output dimension, determine whether to aggregate or concatenate MVM integrations results from the first tile with the second tile.

4. The AIMC system of claim 3, wherein the programmable logic controller is further configured to:
upon a determination that input vectors arrived faster than a time required to execute a single integration:
forward the counter value to the second tile;
reset the counter value in the register of the ADC;
perform a third MVM integration on the third tier;
obtain a third result from the third MVM integration performed on the third tier;
perform a fourth MVM integration on the fourth tier;
obtain a fourth result from the fourth MVM integration performed on the fourth tier; and
aggregate the third result with the fourth result, wherein the aggregated result of the third result and the fourth result is represented as a new counter value in the register of the ADC.

5. The AIMC system of claim 3, wherein the programmable logic controller is further configured to:
upon a determination that input vectors arrived slower than a time required to execute a single integration:
load a first input dimension input vector to a DAC register;
perform the first MVM integration on the first tier of the first tile;
obtain the first result from the first MVM integration performed on the first tier;
store the first result as a first stored counter value in the register of the ADC;
perform a third MVM integration on the third tier of the second tile;
obtain a third result;
store the third result as a second stored counter value in the register of the ADC;
load a second input dimension input vector to the DAC register;
load the stored first counter value;
perform the second MVM integration on the second tier of the first tile;
store the second result as a third stored counter value in the register of the ADC;
load the second stored counter value;
perform a fourth MVM integration on the fourth tier; and
obtain a fourth result from the fourth MVM integration performed on the fourth tier.

6. The AIMC system of claim 5, wherein a first final result of the first tile is concatenated with a second final result of the second tile.

7. The AIMC system of claim 1, further comprising a configurable switch coupled to the programmable logic controller, wherein the configurable switch is programmed by the programmable logic controller to select a counter value from the register of counters used in a current MVM integration operation.

8. The AIMC system of claim 1, further comprising a down-sampling module coupled to the programmable logic controller, wherein the down-sampling module is configured to reduce a number of voltage pulses by a discrete frequency.

9. The AIMC system of claim 8, further comprising a configurable switch coupled to the programmable logic controller, wherein:
the configurable switch is programmed by the programmable logic controller to select a counter value from the register of counters used in a current MVM integration operation; and
the down-sampling module is disposed to provide the reduced number of voltage pulses, from a programmed input number of voltage pulses, to the configurable switch.

10. The AIMC system of claim 1, wherein the programmable logic controller is configured to use bit-serial input encoding with a sliding window process, in the register of counters in the ADC.

11. The AIMC system of claim 1, wherein the programmable logic controller is configured to use bit-serial input encoding with a bit right shift process, in the register of counters in the ADC.

12. The AIMC system of claim 1, wherein the programmable logic controller is configured to map a convolutional layer across multiple tiers of multiple tiles.

13. An analog in-memory computing (AIMC) system, comprising:
a plurality of tiles;
a plurality of vertically stacked tiers for each tile, wherein each tier comprises a crossbar of resistive memory devices on each tier, including a plurality of columns, wherein the crossbar is configured to encode a matrix of weights;
a digital to analog convert (DAC) shared by the plurality of tiles, wherein the DAC is configured to encode an input vector to voltage pulses applied on the crossbar;
an analog to digital converter (ADC) shared by the plurality of tiles, and including a register of counters, wherein the ADC is configured to measure an induced current on each column of the crossbar and digitize the induced current into a digital value; and
a programmable logic controller coupled to the plurality of tiles, the DAC, and to the ADC, wherein the programmable logic controller is configured to:
control the ADC to retain integration values between integrations performed for each tier; and
perform an accumulation of partial integration results in-situ of the tile.

14. The AIMC system of claim 13, wherein the programmable logic controller is configured to aggregate partial integration results of tiers on a same tile.

15. The AIMC system of claim 13, wherein the programmable logic controller, upon determining that an output dimension of the matrix of weights exceeds a capacity of the crossbar of resistive memory devices, is configured to concatenate partial results from a first tier with partial results of a second tier.

16. The AIMC system of claim 13, further comprising a configurable switch coupled to the programmable logic controller, wherein:
the configurable switch is programmed by the programmable logic controller to select a counter value from the register of counters used in a current matrix vector multiplication (MVM) integration operation; and
a down-sampling module is disposed to provide a reduced number of voltage pulses, from a programmed input number of voltage pulses, to the configurable switch.

17. The AIMC system of claim 13, wherein the programmable logic controller is configured to use bit-serial input encoding with a sliding window process, in the register of counters in the ADC.

18. The AIMC system of claim 13, wherein the programmable logic controller is configured to use bit-serial input encoding with a bit right shift process, in the register of counters in the ADC.

19. The AIMC system of claim 13, wherein the programmable logic controller is configured to map a convolutional layer across multiple tiers of multiple tiles.

20. A programmable logic controller in an analog in-memory computing (AIMC) system, wherein the programmable logic controller includes instructions configured to:
control an analog to digital converter (ADC) coupled to a multi-tier tile, to retain integration values between integrations performed for each tier in the multi-tier tile; and
perform an accumulation of partial integration results in-situ of a tile.
